(19) United States
(12) Patent Application Publication
(10) Pub. No.: US 2014/0300345 A1
(43) Pub. Date: Oct. 9, 2014

(54) INTELLIGENT MAGNETIC LATCHING MINIATURE CIRCUIT BREAKER

(71) Applicant: Zhenyang LIU, (US)

(72) Inventor: Zhenyang Liu, Nanjing (CN)

(21) Appl. No.: 14/129,293

(22) PCT Filed: Dec. 13, 2012
(86) PCT No.: PCT/CN2012/001694

§ 371 Date: Dec. 26, 2013

(30) Foreign Application Priority Data
Dec. 26, 2011 (CN) 201110442213.6

(51) Int. Cl. G01R 1/30; H01H 50/42

(52) U.S. Cl. CPC G01R 1/30; H01H 50/42
USPC 324/114; 335/170

(57) ABSTRACT

This invention discloses a type of intelligent magnetic-hold miniature circuit breaker, comprising a casing, a magnetic-hold relay, and a drive circuit, wherein said drive circuit receives control signal and then drives operation of said magnetic-hold relay; said magnetic-hold relay comprises a dynamic spring assembly, a static spring assembly, a deflector rod, a pushing piece, and a magnetic steel assembly. Said miniature circuit breaker also includes a central processor, a communication chip, and a metering module. Said metering module is used to measure power, voltage, and current, and transmit the data to said central processor. This invention breaks through traditional miniature circuit breaker design concept and integrates magnetic-hold relay, central processor, current transformer, metering chip, and communication chip in the casing so that this miniature circuit breaker features protection, metering, control, and communication functions.

### CROSS-REFERENCE TO RELATED APPLICATIONS

This application claims priority from CN Application No. 201110442213.6, filed Dec. 26, 2011 and PCT Application No. PCT/CN2012/001694, filed Dec. 13, 2012, the contents of which are incorporated herein in the entirety by reference.

### FIELD OF THE INVENTION

This invention relates to a type of circuit breaker, in particular an intelligent magnetic-hold miniature circuit breaker in the field of miniature circuit breaker.

### BACKGROUND OF THE INVENTION

Miniature circuit breaker is a type of terminal protection electric appliance most widely used for building electric terminal power distribution devices. Miniature circuit breaker is just a type of mechanical switching electric appliance with limited functions and its normal operations are only manual. This electric appliance cannot satisfy ever higher requirements on power distribution system informatization, networking, intelligentization, and multiple functions. Development of a type of multi-function intelligent miniature circuit breaker has become the grand trend and the direction of miniature circuit breaker.

Magnetic-hold relay is a new type of relay developed in recent years. It is also a type of automatic switch. Originally, magnetic-hold relay is mainly used for electricity meters that allow prepaid charging using IC card and centralized meter reading. Although magnetic-hold relay is a type of automatic switch, it can only be applied with a matching control circuit. In particular, existing magnetic-hold relays lack overload protection function and the function of complete coordination between manual operation and automatic operation.

With advent of the age of Internet of Things, intelligent home is gradually entering ordinary households, so that development of home miniature circuit breaker of reliable performance, simple structure, easy manufacture, and low cost, satisfying habit of common people, and providing intelligent control, is urgent.

### SUMMARY OF THE INVENTIONS

This invention is aimed to overcome aforesaid technical disadvantages of prior art and provide a type of intelligent magnetic-hold miniature circuit breaker and its control method with coordinated manual/automatic operations, overload protection, and metering function, meeting low voltage one-pole (1P) miniature circuit breaker outline standard.

Technical scheme of this invention: A type of intelligent magnetic-hold miniature circuit breaker, comprising a casing, a magnetic-hold relay, and a drive circuit, wherein said drive circuit receives control signal and then drives operation of said magnetic-hold relay; said magnetic-hold relay comprises a dynamic spring assembly, a static spring assembly, a deflector rod, a pushing piece, and a magnetic steel assembly; rotation of said magnetic steel assembly drives said deflector rod and then closing or opening of contacts of said dynamic spring assembly and said static spring assembly via said pushing piece; wherein said miniature circuit breaker also includes a central processor, a communication chip, and a metering module; said communication chip is connected to said central processor, used for information interaction between said central processor and outside; said central processor is connected to said drive circuit, to transmit control signal to said drive circuit; and said metering module is used to measure power, voltage, and current, and transmit the data to said central processor.

Said metering module comprises a voltage conditioning circuit, a current conditioning circuit, a mutual inductance module, and a metering chip; one end of said voltage conditioning circuit is connected to extension wire of said static spring assembly, and the other end is connected to said metering chip; said mutual inductance module is connected to said current conditioning circuit and installed on the extension wire of said dynamic spring assembly; and one end of said metering chip is connected to said current conditioning circuit, and the other end is connected to said central processor.

Said metering chip can be integrated with said central processor to become one chip.

Said mutual inductance module can be current transformer or Hall element or manganese-copper resistor.

Said voltage conditioning circuit adopts resistor voltage division mode to acquire metering chip ADC voltage signal input.

Said current conditioning circuit adopts a resistance network to process output current signal of said mutual inductance module to ADC voltage signal input of said metering chip. Said voltage conditioning circuit and current conditioning circuit are configured according to functions of said metering chip adopted. Metered parameters are obtained by processing using said metering chip. In particular, real-time requirement applies to processing of effective current. Said central processor acquires effective current in real-time to realize overload protection and short circuit protection.

A power supply module is provided to supply power to circuit or module in said casing. Said power supply module comprises a capacitor step-down module, a full wave rectification module, a filtering module, and a voltage stabilization module; said capacitor step-down module realizes connection to live wire via current limiting; and said full wave rectification module can increase the current to reduce volume of the HV capacitor in said capacitor step-down module.

The magnetic-hold relay is the critical component of this invention. In existing mature technology, rated current of magnetic-hold relay is 80 A, but its outline does not satisfy requirements by this invention. It is necessary to design parts of magnetic-hold relay and casing internal structure to an integral assembly to satisfy casing outline fully compatible with low voltage one pole (1P) miniature circuit breaker outline standard.

Miniature circuit breaker standard (GB10963.1-2005) clearly specifies required indices on contact breaking capacity and experiment code, while indices of contact breaking capacity required by magnetic-hold relay standard (JB/T10923-2010) are lower than those specified by the miniature circuit breaker standard. Therefore, based on existing magnetic-hold relay standard, overload protection adopted for this invention can only be realized by complementation using an electronic control part, with hardware circuits simplified by software. Although open state and closed state of contact of magnetic-hold relay are maintained by the magnetic force generated by a permanent magnet at other times, for opening or closing of this contact, just use positive or negative DC pulse voltage to energize the coil, so that this relay can convert open state and closed state in an instant. However, since the DC pulse voltage is 9V (7.5V-13.5V), its current is 100 mA and its pulse width is 80-100 ms, this invention needs to design power supply satisfying requirements in a limited space. The difficulty of design of the electronic part is miniaturization: while metering part and MCU can be miniaturized by chip type selection, power supply cannot be miniaturized by type selection, and innovative design is required to this end.

This invention adopts central processor (STC11F04E), metering chip (CS5463-ISZ), and 485 chip (SN75176) of high integration density as core. Hardware circuit system of this intelligent magnetic-hold miniature circuit breaker is constructed by configuration of corresponding peripheral circuit and power supply.

Compared with prior art, this invention adopts miniature circuit breaker outline standard and directly assembles the magnetic-hold relay of rated current of 80 A inside the casing of this intelligent magnetic-hold miniature circuit breaker, not only improving resistance to interference between strong power source part and weak power source part, but also effectively saving space inside casing of this miniature circuit breaker. This invention breaks through the mechanical switching mode of miniature circuit breakers, and replaces mechanical switch by magnetic-hold relay technique. Through integrated design of casing and magnetic-hold relay, space is reserved for installation of the electronic part.

In terms of functions, this invention realizes manual and remote opening and closing of line in normal state and protections (overload protection and short circuit protection) in abnormal state. Circuit breaker status can be acquired remotely. As expanded function, metering can be realized and metering data can be acquired remotely.

This invention provides high precision metering function to allow understanding of electric appliance energy consumption at any moment to facilitate energy saving. In case of fault in the line resulting in short circuit, this device can automatically open to realize overload protection. Its remote control function can control electric appliance in many modes.

This invention breaks through traditional miniature circuit breaker design concept and integrates magnetic-hold relay, central processor, current transformer, metering chip, and communication chip inside the casing of said miniature circuit breaker, so that this circuit breaker features protection, metering, control, and communication functions, realizing a type of highly intelligent magnetic-hold miniature circuit breaker truly satisfying multi-function and intelligent requirements on miniature circuit breaker.

### BRIEF DESCRIPTION OF THE DRAWINGS

FIG. 1 is an outline of existing low voltage one pole (1P) miniature circuit breaker.

FIG. 2 is a structural schematic of this invention.

FIG. 3 is a structural block diagram of the circuits of this invention.

FIG. 4 is a schematic of the voltage state circuit of this invention.

FIG. 5 is a schematic of the power supply circuit of this invention.

### DETAILED DESCRIPTION OF PARTICULAR EMBODIMENTS OF THE INVENTION

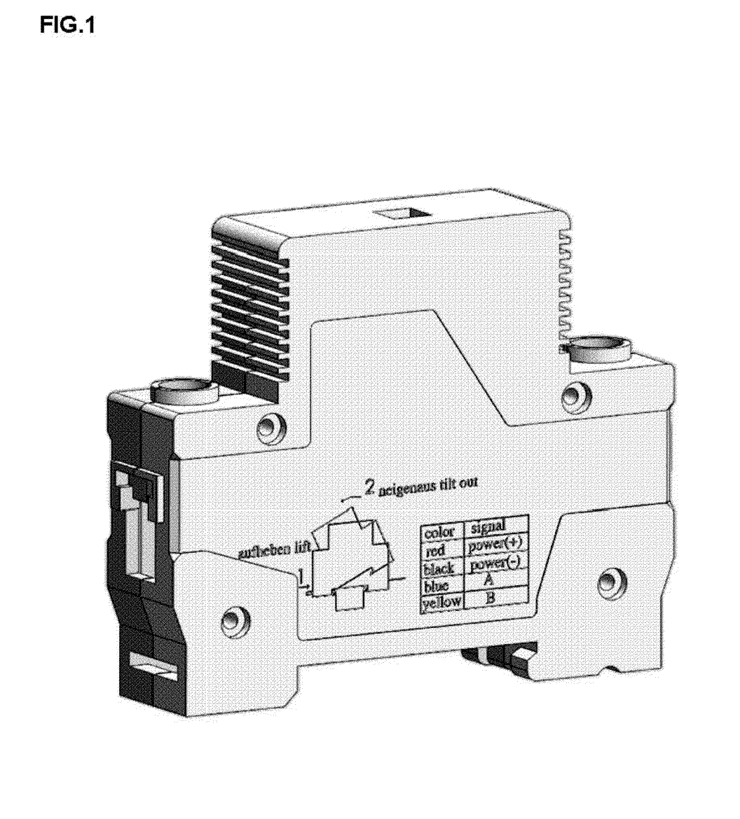

Refer to FIG. 1. The outline of this invention adopts the outline of existing low voltage one-pole (1P) miniature circuit breaker, assembled between a pedestal and an upper cover using rivets, embedded into guide rail using the mode specified by national standard GB10963, and fixed onto the guide rail using the elasticity of a snap board, realizing full compatibility with outline and installation mode of existing low voltage one-pole (1P) miniature circuit breaker.

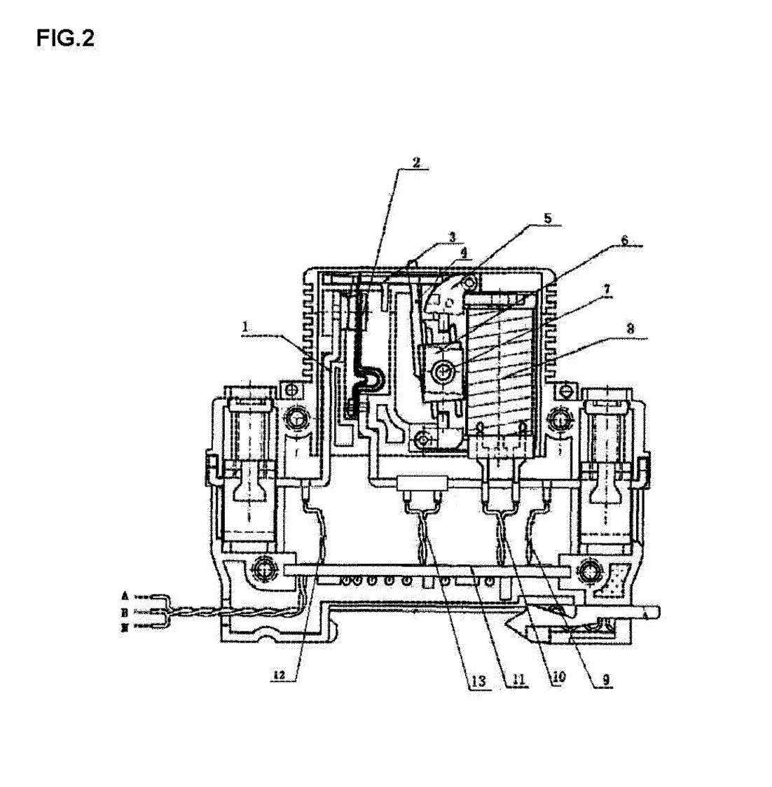

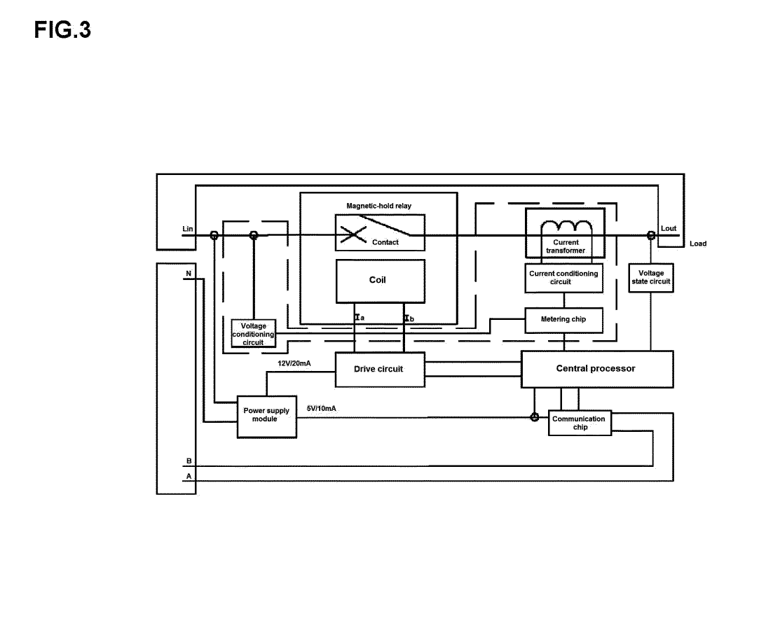

Refer to FIG. 2 and FIG. 3. A type of intelligent magnetic-hold miniature circuit breaker, comprising a casing, a magnetic-hold relay, and a drive circuit, wherein said drive circuit receives control signal and then drives operation of said magnetic-hold relay; said magnetic-hold relay comprises a dynamic spring assembly 2, a static spring assembly 1, a deflector rod 4, a pushing piece 3, a magnetic steel assembly 6, an iron core 8 with wound coil, a yoke iron assembly 5, and a rotating shaft 7; rotation of said magnetic steel assembly 6 drives said deflector rod 4 and then closing or opening of contacts of said dynamic spring assembly 2 and said static spring assembly 1 via said pushing piece 3; and the intelligent controller 11 comprises a central processor, a communication chip, a voltage state circuit, a drive circuit, a power supply module, and a current conditioning circuit. Said metering module is used to measure power, voltage, and current, for transmission to said central processor.

Said metering module comprises a voltage conditioning circuit, a current conditioning circuit, a mutual inductance module, and a metering chip; one end of said voltage conditioning circuit is connected to extension wire of said static spring assembly, and the other end is connected to said metering chip. In this preferred embodiment, said mutual inductance module is a current transformer, installed on extension wire of said dynamic spring assembly via lead wire 13, and connected to said current conditioning circuit; and one end of said metering chip is connected to said current conditioning circuit, and the other end is connected to said central processor.

Said metering chip can be integrated with said central processor to become one chip.

Said mutual inductance module can also be Hall element or manganese-copper resistor.

Said voltage conditioning circuit adopts resistor voltage division mode to acquire metering chip ADC voltage signal input.

Said current conditioning circuit adopts a resistance network to process output current signal of said mutual inductance module to ADC voltage signal input of said metering chip. Said voltage conditioning circuit and current conditioning circuit are configured according to functions of said metering chip adopted. Metered parameters are obtained by processing using said metering chip. In particular, real-time requirement applies to processing of effective current. Said central processor acquires effective current in real-time to realize overload protection and short circuit protection.

Said communication chip is connected to said central processor and used for information interaction between said central processor and outside; said communication chip is provided with interfaces (A, B); said central processor is connected to said drive circuit and used to transmit control signal to said drive circuit; said drive circuit is connected to said magnetic-hold relay via lead wire 10; one end of said voltage state circuit is connected to the extension wire of said dynamic spring assembly 2 via lead wire 9, and the other end is connected to said central processor, used to transmit operating state signal of said magnetic-hold relay to said central processor; and said deflector rod 4 extends out through a hole on said casing to allow manual operation; said communication chip adopts 485 chip; and said central processor adopts STC11F04E of Hoe John.

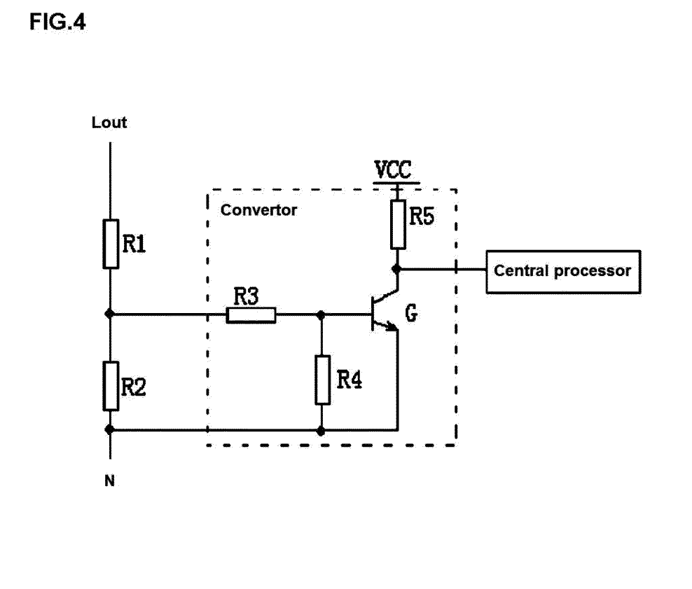

Refer to FIG. 2 and FIG. 4. Said operating state signal is a voltage signal, and said voltage state circuit comprises two resistors R1, R2 and one convertor; wherein one end of the first resistor R1 is connected to the live wire Lout of commercial power supply, i.e. connected to extension wire of dynamic spring assembly 2 via lead wire 9, and the other end is connected to the second resistor R2 and the input end of said convertor, and the other end of said second resistor R2 is earthed (N); wherein the output end of said convertor is connected to said central processor and said convertor converts the voltage generated by voltage division of said two resistors R1, R2 to the input voltage of said central processor.

Said convertor comprises three resistors R3, R4, R5 and one triode G; wherein one end of resistor R3 is used as the input end of said convertor and the other end is connected to resistor R4 and base of said triode G, and the other end of resistor R4 is earthed; wherein emitter of said triode G is connected to one end of resistor R5 and used as output end of said convertor, collector of said triode G is earthed, and the other end of resistor R5 is connected to convertor power supply.

Said resistor R4 and said triode G in said convertor can be replaced by optic couplers for isolation between strong power source and the central processor.

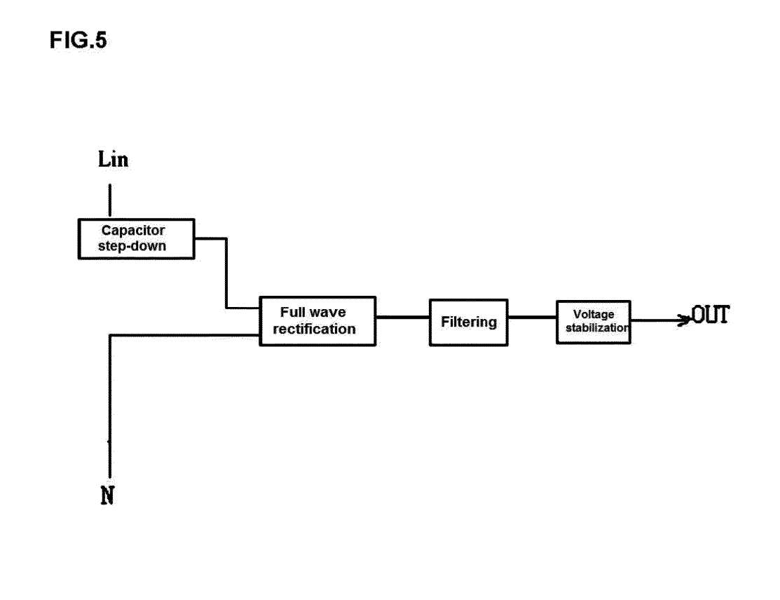

Refer to FIG. 2, FIG. 3, and FIG. 5. A power supply module is also provided to supply power to circuit or module in said casing. Said power supply module is connected to commercial power supply live wire Lin via lead wire 12. Said power supply module comprises a capacitor step-down module, a full wave rectification module, a filtering module, and a voltage stabilization module; said capacitor step-down module realizes connection to commercial power supply live wire via current limiting; and said full wave rectification module can increase the current to reduce volume of the HV capacitor in said capacitor step-down module, so as to realize installation of power supply in the narrow space of existing low voltage one-pole (1P) miniature circuit breaker.

In addition to the above preferred embodiment, this invention may have other implementation modes. All technical schemes that adopt equivalent replacement or equivalent transformation shall fall within scope of protection requested by this invention.

1-8. (canceled)

9. An intelligent magnetic-hold miniature circuit breaker, comprising a casing, a magnetic-hold relay, and a drive circuit, a central processor, a communication chip, and a metering module, wherein said drive circuit is for controlling said magnetic-hold relay, which comprises a dynamic spring assembly, a static spring assembly, a deflector rod, a pushing piece, and a magnetic steel assembly, said communication chip is connected to said central processor which is connected to said drive circuit for transmitting control signals thereto, and said metering module is responsible for measuring power, voltage, and current, and transmitting data to said central processor.

10. The intelligent magnetic-hold miniature circuit breaker according to claim 9, wherein said metering module comprises a voltage conditioning circuit, a current conditioning circuit, a mutual inductance module, and a metering chip, one end of said voltage conditioning circuit is connected to an extension wire of said static spring assembly, and another end of said voltage conditioning circuit is connected to said metering chip, said mutual inductance module is connected to said current conditioning circuit and installed on an extension wire of said dynamic spring assembly; and one end of said metering chip is connected to said current conditioning circuit and another end is connected to said central processor.

11. The intelligent magnetic-hold miniature circuit breaker according to claim 10, wherein said metering chip is integrated within said central processor.

12. The intelligent magnetic-hold miniature circuit breaker according to claim 10, wherein said mutual inductance module is a current transformer, a Hall element or a manganese-copper resistor.

13. The intelligent magnetic-hold miniature circuit breaker according to claim 10, wherein said voltage conditioning circuit has a resistor voltage division mode to acquire metering chip ADC voltage signal input.

14. The intelligent magnetic-hold miniature circuit breaker according to claim 10, wherein said current conditioning circuit has a resistance network to process output current signals of said mutual inductance module into ADC voltage signals as input of said metering chip;

15. The intelligent magnetic-hold miniature circuit breaker according to claim 9, further comprising a power supply module to supply power to circuits or modules in said casing.

16. The intelligent magnetic-hold miniature circuit breaker according to claim 15, wherein said power supply module comprises a capacitor step-down module, a full wave rectification module, a filtering module, and a voltage stabilization module.
